(19) United States
(12) Patent Application Publication
(10) Pub. No.: US 2021/0098672 A1
(43) Pub. Date: Apr. 1, 2021

(54) THERMOELECTRIC CONVERSION MODULE

(71) Applicant: LINTEC CORPORATION, Itabashi-ku (JP)

(72) Inventors: Kunihisa KATO, Warabi-shi (JP); Tsuyoshi MUTO, Saitama-shi (JP); Yuma KATSUTA, Gyoda-shi (JP)

(73) Assignee: LINTEC CORPORATION, Itabashi-ku (JP)

(21) Appl. No.: 17/041,063

(22) PCT Filed: Mar. 25, 2019
(86) PCT No.: PCT/JP2019/012295

§ 371 Date: Sep. 24, 2020

(30) Foreign Application Priority Data
Mar. 26, 2018 (JP) 2018-058458

(51) Int. Cl. H01L 35/08; H01L 35/16; H01L 35/32; H01L 35/34

(52) U.S. Cl. CPC H01L 35/08; H01L 35/34; H01L 35/32; H01L 35/16

(57) ABSTRACT

Provided is a thermoelectric conversion module that improves the solderability between a thermoelectric element layer containing a resin and a solder layer. The thermoelectric conversion module includes a first substrate having a first electrode, a second substrate having a second electrode, a thermoelectric element layer, a solder-receiving layer that directly bonds to the thermoelectric element layer, and a solder layer, wherein the first electrode of the first substrate and the second electrode of the second substrate face each other, and wherein the thermoelectric element layer is formed of a thin film of a thermoelectric semiconductor composition containing a resin, and the solder-receiving layer contains a metal material.

### TECHNICAL FIELD

The present invention relates to a thermoelectric conversion module that carries out energy interconversion between heat and electricity.

### BACKGROUND ART

Heretofore, there is known a device that enables direct interconversion between heat energy and electric energy by a thermoelectric conversion module having a thermoelectric effect such as a Seebeck effect and a Peltier effect, as one means of effective energy utilization.

As the thermoelectric conversion module, use of a so-called π-type thermoelectric conversion device is known. Regarding the π-type device, a pair of electrodes spaced from each other are arranged on a substrate and, for example, a P-type thermoelectric element is arranged on one electrode while an N-type thermoelectric element is on the other electrode, as similarly spaced from each other, and the upper faces of the two thermoelectric semiconductor materials are connected to the electrodes of a facing substrate to constitute such a π-type device. In addition, use of a so-called in-plane-type thermoelectric conversion device is known. Regarding the in-plane-type device, plural thermoelectric elements are aligned in such a manner that N-type thermoelectric elements and P-type thermoelectric elements are alternately arranged, and for example, the lower electrodes of the thermoelectric elements are connected in series to constitute such an in-plane-type device.

On the other hand, recently, there are demands for improving the flexibility of thermoelectric conversion modules, thinning the modules and improving the thermoelectric performance thereof. For satisfying these demands, for example, a resin substrate of polyimide or the like is used as a substrate for thermoelectric conversion modules from the viewpoint of heat resistance and flexibility thereof. Further, a technique of forming a thin film of a resin-containing thermoelectric semiconductor composition as a thermoelectric element layer is under investigation in the art from the viewpoint of thinning and flexibility of the layer.

In such situations, PTL 1 discloses a technique of bonding a resin-containing thermoelectric element layer and an electrode with a conductive adhesive in a thermoelectric conversion module using a π-type thermoelectric conversion element (Peltier cooling element).

### CITATION LIST

### Patent Literature

PTL 1: WO 2016/104615

### SUMMARY OF INVENTION

### Technical Problem

In PTL 1, however, the resin-containing thermoelectric element layer and the electrode are bonded via a conductive adhesive layer of an epoxy resin-based, acrylic resin-based or urethane resin-based adhesive containing a metal filler, and therefore the device could not have a sufficiently high thermal conductivity and further improvement in thermal conductivity is desired.

As a result of investigations, the present inventors have found another problem that, when a solder layer is used in place of the conductive adhesive layer, the resin-containing thermoelectric element layer could not be bonded to the solder layer.

An object of the present invention is to provide a thermoelectric conversion module in which the resin-containing thermoelectric element layer and the solder layer realize improved bonding performance.

### Solution to Problem

The present inventors have assiduously made repeated studies for solving the above-mentioned problems and, as a result, have found that, in bonding a resin-containing thermoelectric element layer and an electrode via a solder layer to constitute a thermoelectric conversion module, when a solder-receiving layer that contains a metal material is arranged between the thermoelectric element layer and the solder layer, then the bonding performance between the thermoelectric element layer and the solder layer is improved, and have completed the present invention.

Specifically, the present invention provides the following (1) to (9):
(1) A thermoelectric conversion module including a first substrate having a first electrode, a second substrate having a second electrode, a thermoelectric element layer, a solder-receiving layer that directly bonds to the thermoelectric element layer, and a solder layer, wherein the first electrode of the first substrate and the second electrode of the second substrate face each other, and wherein the thermoelectric element layer is formed of a thin film of a thermoelectric semiconductor composition containing a resin, and the solder-receiving layer contains a metal material.
(2) The thermoelectric conversion module according to the above (1), wherein the metal material is at least one selected from the group consisting of gold, silver, aluminum, rhodium, platinum, chromium, palladium, tin and an alloy that contains a metal material of any of these.
(3) The thermoelectric conversion module according to the above (1) or (2), wherein the thickness of the solder-receiving layer is 10 nm to 50 μm.
(4) The thermoelectric conversion module according to any of the above (1) to (3), wherein the resin is a heat-resistant resin.
(5) The thermoelectric conversion module according to the above (4), wherein the heat-resistant resin is a polyimide resin, a polyamide resin, a polyamideimide resin, or an epoxy resin.
(6) The thermoelectric conversion module according to any of the above (1) to (5), wherein the thermoelectric semiconductor composition contains a thermoelectric semiconductor material and the thermoelectric semiconductor material is a bismuth-tellurium-based thermoelectric semiconductor material, a telluride-based thermoelectric semiconductor material, an antimony-tellurium-based thermoelectric semiconductor material, or a bismuth-selenide-based thermoelectric semiconductor material,
(7) The thermoelectric conversion module according to the above (6), wherein the bismuth-tellurium-based thermoelectric semiconductor material is a P-type bismuth telluride, an N-type bismuth telluride, or Bi₂Te₃.
(8) The thermoelectric conversion module according to any of the above (1) to (7), wherein the first substrate and the second substrate each are a polyimide film, a polyamide film, a polyether imide film, a polyaramid film or a polyamideimide film.
(9) The thermoelectric conversion module according to any of the above (1) to (8), wherein the thermoelectric element layer is formed of a thin film of a thermoelectric semiconductor composition further containing an ionic liquid.

### Advantageous Effects of Invention

According to the present invention, there is provided a thermoelectric conversion module capable of improving the bonding performance between a resin-containing thermoelectric element layer and a solder layer therein.

### BRIEF DESCRIPTION OF DRAWINGS

FIG. 1 is a cross-sectional view for explaining an example of a configuration of a thermoelectric conversion module including a solder-receiving layer of the present invention.

FIG. 2 is a cross-sectional view for explaining another example of a configuration of a thermoelectric conversion module including a solder-receiving layer of the present invention.

FIG. 3 is a cross-sectional view showing a configuration of a thermoelectric conversion module (test piece) produced in Examples and Comparative Example.

### DESCRIPTION OF EMBODIMENTS

### [Thermoelectric Conversion Module]

The thermoelectric conversion module of the present invention includes a first substrate having a first electrode, a second substrate having a second electrode, a thermoelectric element layer, a solder-receiving layer that directly bonds to the thermoelectric element layer, and a solder layer, wherein the first electrode of the first substrate and the second electrode of the second substrate face each other, the thermoelectric element layer is formed of a thin film of a thermoelectric semiconductor composition containing a resin, and the solder-receiving layer contains a metal material.

The thermoelectric conversion module of the present invention has a solder-receiving layer that contains a metal material on the thermoelectric element layer that contains a hardly solderable resin, and therefore, for example, the bonding strength of the solder layer used for bonding to the first and/or second electrodes is high.

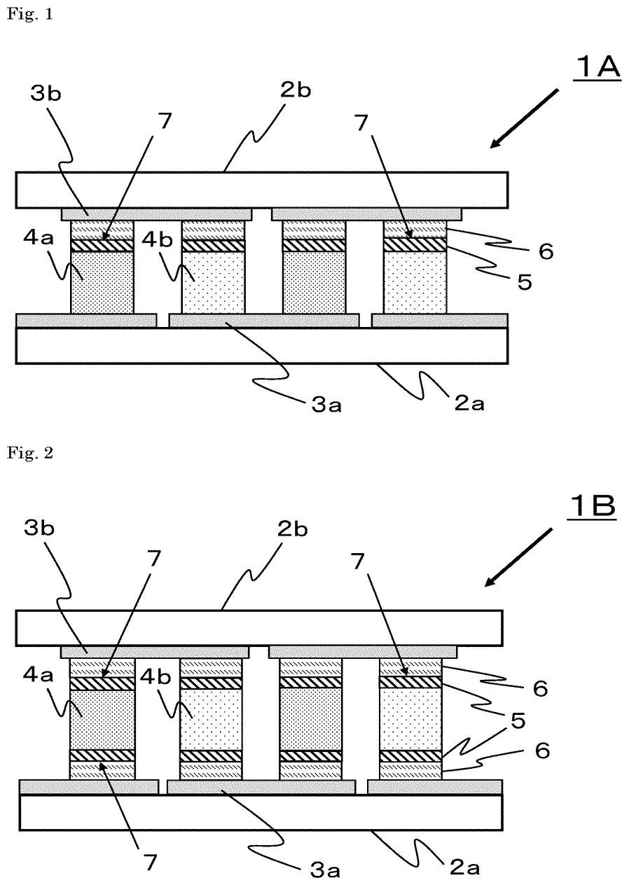

FIG. 1 is a cross-sectional view for explaining an example of a configuration of a thermoelectric conversion module including a solder-receiving layer of the present invention. The thermoelectric conversion module 1A is composed of a so-called n-type thermoelectric conversion element, and has a first substrate 2a and a second substrate 2b facing each other, and includes a P-type thermoelectric element 4a and an N-type thermoelectric element 4b and further a solder-receiving layer 5 and a solder layer 6 in that order between an electrode 3a formed on the first substrate 2a and an electrode 3b formed on the second substrate 2b.

FIG. 2 is a cross-sectional view for explaining another example of a configuration of a thermoelectric conversion module including a solder-receiving layer of the present invention. Similarly, the thermoelectric conversion module 1B is composed of a so-called n-type thermoelectric conversion element, and has a first substrate 2a and a second substrate 2b facing each other, and includes a solder-receiving layer 5 and a solder layer 6 formed in that order on both surfaces of a P-type thermoelectric element 4a and an N-type thermoelectric element 4b between an electrode 3a formed on the first substrate 2a and an electrode 3b formed on the second substrate 2b. In the present invention, the solder-receiving layer 5 is arranged, and accordingly, any one surface or both surfaces on the electrode side of the facing substrate of the P-type thermoelectric element layer 4a and the N-type thermoelectric element layer 4b can be bonded at high reliability via a bonding part 7 to the solder layer 6 via the solder-receiving layer 5.

### <Solder-Receiving Layer>

The thermoelectric conversion module of the present invention uses a solder-receiving layer.

The solder-receiving layer has a function of bonding the thermoelectric element layer containing a resin to the solder layer on the facing electrode side, and is directly bond to the thermoelectric element layer.

The solder-receiving layer contains a metal material. The metal material is preferably at least one selected from the group consisting of gold, silver, aluminum, rhodium, platinum, chromium, palladium, tin and an alloy that contains a metal material of any of the metals. Among these, one formed of gold, silver, aluminum, tin or two layers of gold is more preferred, and from the viewpoint of material cost, high thermal conductivity and bonding stability, silver and aluminum are more preferred.

Further, the solder-receiving layer may also be formed using a paste material that contains a solvent and a resin component, in addition to the metal material. In the case of using a paste material, preferably, the solvent and the resin component are removed by firing or the like, as described below. As the paste material, a silver paste or an aluminum paste is preferred.

The thickness of the solder-receiving layer is preferably 10 nm to 50 μm, more preferably 50 nm to 16 μm, even more preferably 200 nm to 4 μm, especially more preferably 500 nm to 3 μm. When the thickness of the solder-receiving layer falls within the range, the adhesiveness to the surface of the resin-containing thermoelectric element layer and the adhesiveness to the surface of the solder layer on the electrode side are excellent and high-reliability bonding can be attained. In addition, not only electrical conductivity but also thermal conductivity can be kept high, therefore resulting in that the thermoelectric performance of the thermoelectric conversion module is not lowered and is kept good.

The solder-receiving layer may be a single layer of the above-mentioned metal material used directly as such, or two or more metal materials may be laminated to be a multilayer. Also, a composition containing the metal material in a solvent or a resin may be used for forming the layer. However, in this case, from the viewpoint of maintaining high electrical conductivity and high thermal conductivity (maintaining thermoelectric performance), preferably, the resin component including a solvent is removed by firing as the final form of the solder-receiving layer.

The solder-receiving layer is formed using the above-mentioned metal material.

As a method for forming the solder-receiving layer, employable herein is a method that includes forming an unpatterned solder-receiving layer on a thermoelectric element layer followed by patterning the layer to have a predetermined pattern by known physical treatment or chemical treatment or a combination thereof mainly based on photolithography, or a method of directly forming a pattern of a solder-receiving layer according to a screen printing method, a stencil printing method or an inkjet method.

The method for forming an unpatterned solder-receiving layer includes a vacuum film formation method such as PVD (physical vapor deposition) such as a vacuum evaporation method, a sputtering method, or an ion-plating method, or CVD(chemical vapor deposition) such as thermal CVD or atomic layer deposition (ALD), or a wet process of various coating or electrodeposition methods such as a dip coating method, a spin coating method, a spray coating method, a gravure coating method, a die coating method or a doctor blade method, as well as a silver salt method, an electrolytic plating method, an electroless plating method, or lamination of metal foils; and the method may be appropriately selected depending on the material of the solder-receiving layer.

In the present invention, the solder-receiving layer is required to have high electrical conductivity and high thermal conductivity from the viewpoint of maintaining thermoelectric performance, and therefore a solder-receiving layer formed according to a screen printing method, a stencil printing method, an electrolytic plating method, an electroless plating method or a vacuum film formation method is preferably used.

### (Solder Layer)

The solder layer is used for bonding the solder-receiving layer and the electrode on the facing substrate side.

The solder material to constitute the solder layer for use in the present invention may be appropriately selected in consideration of the heatproof temperature as well as the electrical conductivity and the thermal conductivity of the substrate and the resin contained in the thermoelectric element layer, and includes known materials such as Sn, an Sn/Pb alloy, an Sn/Ag alloy, an Sn/Cu alloy, an Sn/Sb alloy, an Sn/In alloy, an Sn/Zn alloy, an Sn/In/Bi alloy, an Sn/In/Bi/Zn alloy, an Sn/Bi/Pb/Cd alloy, an Sn/Bi/Pb alloy, an Sn/Bi/Cd alloy, a Bi/Pb alloy, an Sn/Bi/Zn alloy, an Sn/Bi alloy, an Sn/Bi/Pb alloy, an Sn/Pb/Cd alloy, and an Sn/Cd alloy. From the viewpoint of lead-free and/or cadmium-free composition, melting point, electrical conductivity and thermal conductivity, alloys such as a 43Sn/57Bi alloy, a 42Sn/58Bi alloy, a 40Sn/56Bi/4Zn alloy, a 48Sn/52In alloy, and a 39.8Sn/52In/7Bi/1.2Zn are preferred.

Examples of commercial products of solder materials usable here include a 42Sn/58Bi alloy (from Tamura Corporation, product name: SAM10-401-27), a 41Sn/58Bi/Ag alloy (from Nihon Handa Co., Ltd., product name: PF141-LT7HO), and a 96.5Sn3Ag0.5Cu alloy (from Nihon Handa Co., Ltd., product name: PF305-207BTO).

The thickness of the solder layer (after heated and cooled) is preferably 10 to 200 μm, more preferably 20 to 150 μm, even more preferably 30 to 130 μm, especially more preferably 40 to 120 μm. When the thickness of the solder layer falls within the range and when the thickness of the solder-receiving layer falls within the above-mentioned range, the bonding strength between the thermoelectric element layer and the electrode can be kept high via the solder-receiving layer and the solder layer.

### <Thermoelectric Element Layer>

The thermoelectric element layer for use in the thermoelectric conversion module of the present invention is formed of a thin film of a thermoelectric semiconductor composition containing a resin. Preferably, the layer is formed of a thin film of a thermoelectric semiconductor composition containing a thermoelectric semiconductor material (hereinunder may be referred to as “thermoelectric semiconductor fine particles”), a heat-resistant resin to be mentioned below, and further one or both of an ionic liquid and an inorganic ionic compound to be mentioned below.

### (Thermoelectric Semiconductor Material)

The thermoelectric semiconductor material for use in the present invention, namely the thermoelectric semiconductor material to constitute the P-type thermoelectric element layer and the N-type thermoelectric element layer is not specifically limited so far as the material is one capable of generating a thermoelectric force when given a temperature difference, and examples thereof include a bismuth-tellurium-based thermoelectric semiconductor material such as a P-type bismuth telluride, and an N-type bismuth telluride; a telluride-based thermoelectric semiconductor material such as GeTe and PbTe; an antimony-tellurium-based thermoelectric semiconductor material; a zinc-antinomy-based thermoelectric semiconductor material such as ZnSb, Zn₃Sb_{2, and} Zn₄Sb₃; a silicon-germanium-based thermoelectric semiconductor material such as SiGe; a bismuth-selenide-based thermoelectric semiconductor material such as Bi₂Se₃; a silicide-based thermoelectric semiconductor material such as 6-FeSi₂, CrSi₂, MnSi_{1.73}, and Mg₂Si; an oxide-based thermoelectric semiconductor material; a Heusler material such as FeVAl, FeVAlSi, and FeVTiAl; and a sulfide-based thermoelectric semiconductor material such as TiS₂.

Among these, a bismuth-tellurium-based thermoelectric semiconductor material, a telluride-based thermoelectric semiconductor material, an antimony-tellurium-based thermoelectric semiconductor material or a bismuth-selenide-based thermoelectric semiconductor material is preferred.

Further, a bismuth-tellurium-based thermoelectric semiconductor material such as a P-type bismuth telluride or an N-type bismuth telluride is more preferred.

The carrier of the P-type bismuth telluride is a hole and the Seebeck coefficient thereof is positive, for which, for example, preferably used is one represented by Bi_{X}Te₃Sb_{2-X}. In this case, X preferably satisfies 0<X≤0.8, more preferably 0.4≤X≤0.6. X being more than 0 and 0.8 or less is preferred since the Seebeck coefficient and the electrical conductivity of the material are large and the material can maintain the characteristics of a P-type thermoelectric element.

The carrier of the N-type bismuth telluride is an electron and the Seebeck coefficient thereof is negative, for which, for example, preferably used is one represented by Bi₂Te_{3-Y}Se_{Y}. In this case, Y is preferably 0≤Y≤3 (when Y=0, Bi₂Te₃), more preferably 0≤Y≤2.7. Y being 0 or more and 3 or less is preferred since the Seebeck coefficient and the electrical conductivity of the material are large and the material can maintain the characteristics of an N-type thermoelectric element.

The blending amount of the thermoelectric semiconductor material or the thermoelectric semiconductor fine particles in the thermoelectric semiconductor composition is preferably 30 to 99% by mass. The amount is more preferably 50 to 96% by mass, even more preferably 70 to 95% by mass. The blending amount of the thermoelectric semiconductor fine particles falling within the above range is preferred since the Seebeck coefficient (absolute value of Peltier coefficient) is large, the electrical conductivity reduction can be prevented, only the thermal conductivity is lowered, and therefore the composition exhibits high-level thermoelectric performance and can form a film having a sufficient film strength and flexibility.

The average particle size of the thermoelectric semiconductor fine particles is preferably 10 nm to 200 μm, more preferably 10 nm to 30 μm, even more preferably 50 nm to 10 μm, and especially preferably 1 to 6 μm. Falling within the range, uniform dispersion is easy and electrical conductivity can be increased.

The thermoelectric semiconductor fine particles are preferably those prepared by finely grinding the above-mentioned thermoelectric semiconductor material into a predetermined size using a fine grinding device.

The method of producing the thermoelectric semiconductor fine particles by finely grinding the thermoelectric semiconductor material is not specifically defined, and the material may be ground into a predetermined size, using a known fine grinding mill or the like, such as a jet mill, a ball mill, a bead mill, a colloid mill, or a roller mill.

The average particle size of the thermoelectric semiconductor fine particles may be measured with a laser diffraction particle sizer (Master Sizer 3000 from Malvern Corporation), and the median value of the particle size distribution is taken as the average particle size.

Preferably, the thermoelectric semiconductor fine particles are annealed. (Hereinafter the annealing may be referred to as annealing treatment A.) The annealing treatment A increases the crystallinity of the thermoelectric semiconductor fine particles and further increases the Seebeck coefficient or the Peltier coefficient of the thermoelectric conversion material since the surface oxide film of the thermoelectric semiconductor fine particles could be removed, therefore further increasing the figure of merit thereof. Not specifically defined, the annealing treatment A is preferably carried out in an inert gas atmosphere such as nitrogen or argon in which the gas flow rate is controlled or in a reducing gas atmosphere such as hydrogen in which also the gas flow rate is controlled, or in a vacuum condition, and is more preferably carried out in a mixed gas atmosphere of an inert gas and a reducing gas. Specific temperature conditions depend on the thermoelectric semiconductor fine particles to be used, but in general, it is desirable that the treatment is carried out at a temperature not higher than the melting point of the fine particles but falling between 100 and 1,500° C., for a few minutes to several tens hours.

### (Resin)

The resin for use in the present invention is, from the viewpoint of annealing the thermoelectric element layer at a high temperature as annealing acts as a binder between the thermoelectric semiconductor material (thermoelectric semiconductor fine particles) and enhances the flexibility of the thermoelectric conversion module, and in addition, the resin can facilitate formation of a thin film by coating. The heat-resistant resin is not specifically defined but is preferably one that can maintain various physical properties thereof such as mechanical strength and thermal conductivity thereof as a resin without losing them in crystal growth of the thermoelectric semiconductor fine particles through annealing treatment of the thin film of the thermoelectric semiconductor composition.

The heat-resistant resin is preferably a polyamide resin, a polyamideimide resin, a polyimide resin or an epoxy resin from the viewpoint that the heat resistance thereof is higher and that the resin has no negative influence on the crystal growth of the thermoelectric semiconductor fine particles in the thin film, and is more preferably a polyamide resin, a polyamideimide resin or a polyimide resin from the viewpoint of excellent flexibility thereof. In the case where a polyimide film is used as the substrate, the heat-resistant resin is more preferably a polyimide resin from the viewpoint of adhesiveness thereof to the polyimide film. In the present invention, polyimide resin is a generic term for polyimide and its precursors.

Preferably, the decomposition temperature of the heat-resistant resin is 300° C. or higher. When the decomposition temperature falls within the above range, the resin does not lose the function thereof as a binder and can maintain flexibility even when the thin film of the thermoelectric semiconductor composition is annealed, as described below.

Preferably, the mass reduction in the heat-resistant resin at 300° C. in thermogravimetry (TG) is 10% or less, more preferably 5% or less, even more preferably 1% or less. When the mass reduction falls within the above range, the resin does not lose the function thereof as a binder and can maintain the flexibility of the thermoelectric element even when the thin film of the thermoelectric semiconductor composition is annealed, as described below.

The blending amount of the heat-resistant resin in the thermoelectric semiconductor composition is preferably 0.1 to 40% by mass, more preferably 0.5 to 20% by mass, even more preferably 1 to 20% by mass, still more preferably 2 to 15% by mass. When the blending amount of the heat-resistant resin falls within the above range, the thermoelectric semiconductor material functions as a binder, and facilitates formation of a thin film to give a film satisfying both high-level thermoelectric performance and a high film strength, and a resin part can exist on the outer surface of the thermoelectric element layer.

### (Ionic Liquid)

The ionic liquid for use in the present invention is a molten salt of a combination of a cation and an anion, which can exist as a liquid in a broad temperature range of −50 to 500° C. The ionic liquid is characterized in that it has an extremely low vapor pressure and is nonvolatile, has excellent thermal stability and electrochemical stability, has a low viscosity and has a high ionic conductivity, and therefore, serving as a conductive assistant, the ionic liquid can effectively prevent reduction in the electrical conductivity between thermoelectric semiconductor fine particles. In addition, the ionic liquid has high polarity based on the aprotic ionic structure thereof, and is excellent in compatibility with the heat-resistance resin, and therefore can make the thermoelectric element layer have a uniform electrical conductivity.

The ionic liquid for use herein may be a known one or a commercially-available one. Examples thereof include those composed of a cation component of a nitrogen-containing cyclic cation compound such as pyridinium, pyrimidinium, pyrazolium, pyrrolidinium, piperidinium or imidazolium, or a derivative thereof, an amine-type cation such as tetraalkylammonium, or a derivative thereof, a phosphine-type cation such as phosphonium, trialkyl sulfonium or tetraalkyl phosphonium, or a derivative thereof, or a lithium cation or a derivative thereof, and an anion component of a chloride ion such as Cl⁻, AlCl₄⁻, Al₂Cl₇⁻ or ClO₄⁻, a bromide ion such as Br⁻, an iodide ion such as I⁻, a fluoride ion such as BF₄⁻ or PF₆⁻, a halide anion such as F(HF)ₙ⁻, or any other anion component such as NO₃⁻, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)n⁻, (CN)₂N⁻, C₄F₉SO₃⁻, (C₂F₅SO₂)₂N⁻, C₃F₇COO⁻, or (CF₃SO₂)(CF₃CO)N⁻.

Among the above-mentioned ionic liquids, it is preferable that, from the viewpoint of enhancing high-temperature stability and compatibility between thermoelectric semiconductor fine particles and resin, and preventing reduction in the electrical conductivity between thermoelectric semiconductor fine particles, the cation component in the ionic liquid contains at least one selected from a pyridinium cation and a derivative, and an imidazolium cation and a derivative thereof. It is also preferable that the anion component of the ionic liquid contains a halide anion, more preferably at least one selected from Cl⁻, Br⁻ and I⁻.

Specific examples of the ionic liquid in which the cation component contains a pyridinium cation or a derivative thereof include 4-methyl-butylpyridinium chloride, 3-methyl-butylpyridinium chloride, 4-methyl-hexylpyridinium chloride, 3-methyl-hexylpyridinium chloride, 4-methyl-octylpyridinium chloride, 3-methyl-octylpyridinium chloride, 3,4-dimethyl-butylpyridinium chloride, 3,5-dimethyl-butylpyridinium chloride, 4-methyl-butylpyridinium tetrafluoroborate, 4-methyl-butylpyridinium hexafluorophosphate, 1-butyl-4-methylpyridinium bromide, 1-butyl-4-methylpyridinium hexafluorophosphate, and 1-butyl-4-methylpyridinium iodide. Among these, 1-butyl-4-methylpyridinium bromide, 1-butyl-4-methylpyridinium hexafluorophosphate and 1-butyl-4-methylpyridinium iodide are preferred.

Specific examples of the ionic liquid in which the cation component contains an imidazolium cation or a derivative thereof include [1-butyl-3-(2-hydroxyethyl)imidazolium bromide], [1-butyl-3-(2-hydroxyethyl)imidazolium tetrafluoroborate], 1-ethyl-3-methylimidazolium chloride, 1-ethyl-3-methylimidazolium bromide, 1-butyl-3-methylimidazolium chloride, 1-hexyl-3-methylimidazolium chloride, 1-octyl-3-methylimidazolium chloride, 1-decyl-3-methylimidazolium chloride, 1-decyl-3-methylimidazolium bromide, 1-dodecyl-3-methylimidazolium chloride, 1-tetradecyl-3-methylimidazolium chloride, 1-ethyl-3-methylimidazolium tetrafluoroborate, 1-butyl-3-methylimidazolium tetrafluoroborate, 1-hexyl-3-methylimidazolium tetrafluoroborate, 1-ethyl-3-methylimidazolium hexafluorophosphate, 1-butyl-3-methylimidazolium hexafluorophosphate, 1-methyl-3-butylimidazolium methylsulfate, and 1,3-dibutylimidazolium methylsulfate. Among these, [1-butyl-3-(2-hydroxyethyl)imidazolium bromide] and [1-butyl-3-(2-hydroxyethyl)imidazolium tetrafluoroborate] are preferred.

Preferably, the ionic liquid has an electrical conductivity of 10⁻⁷ S/cm or more, more preferably 10⁻⁶ S/cm or more. When the electrical conductivity falls within the above range, the ionic liquid can effectively prevent reduction in the electrical conductivity between thermoelectric semiconductor fine particles, serving as a conductive assistant.

Also preferably, the decomposition temperature of the ionic liquid is 300° C. or higher. When the decomposition temperature falls within the above range, the ionic liquid can still maintain the effect thereof as a conductive assistant even when the thin film of the thermoelectric semiconductor composition is annealed, as described below.

Preferably, the mass reduction in the ionic liquid at 300° C. in thermogravimetry (TG) is 10% or less, more preferably 5% or less, even more preferably 1% or less. When the mass reduction falls within the above range, the ionic liquid can still maintain the effect thereof as a conductive assistant even when the thin film of the thermoelectric semiconductor composition is annealed, as described below.

The blending amount of the ionic liquid in the thermoelectric semiconductor composition is preferably 0.01 to 50% by mass, more preferably 0.5 to 30% by mass, even more preferably 1.0 to 20% by mass. The blending amount of the ionic liquid falling within the above range provides a film capable of effectively preventing electrical conductivity reduction and having high thermoelectric performance.

### (Inorganic Ionic Compound)

The inorganic ionic compound for use in the present invention is a compound composed of at least a cation and an anion. The inorganic ionic compound is solid at room temperature and has a melting point at any temperature falling within a temperature range of 400 to 900° C. and is characterized by having a high ionic conductivity, and therefore, serving as a conductive assistant, the compound can prevent reduction in the electrical conductivity between thermoelectric semiconductor fine particles.

A metal cation is used as the cation.

Examples of the metal cation include an alkali metal cation, an alkaline earth metal cation, a typical metal cation and a transition metal cation, and an alkali metal cation or an alkaline earth metal cation is more preferred.

Examples of the alkali metal cation include Li⁺, Na⁺, K⁺, Rb⁺, Cs⁺ and Fr⁺.

Examples of the alkaline earth metal cation include Mg²⁺, Ca²⁺, Sr²⁺ and Ba²⁺.

Examples of the anion include F⁻, Cl⁻, Br⁻, I⁻, OH⁻, CN⁻, NO₃⁻, NO₂⁻, ClO⁻, ClO₂⁻, ClO₃⁻, ClO₄⁻, CrO₄²⁻, HSO₄⁻, SCN⁻, BF₄⁻, and PF₆⁻.

As the inorganic ionic compound, known or commercially-available ones can be used. Examples thereof include those composed of a cation component such as a potassium cation, a sodium cation or a lithium cation, and an anion component, e.g., a chloride ion such as Cl⁻, AlCl₄⁻, Al₂Cl₇⁻, or ClO₄⁻, a bromide ion such as Br⁻, an iodide ion such as I⁻, a fluoride ion such as BF₄⁻ or PF₆⁻, a halide anion such as F(HF)ₙ⁻, or any other anion component such as NO₃⁻, OH⁻, or CN⁻.

Among the above-mentioned inorganic ionic compounds, those having at least one selected from potassium, sodium and lithium as the cation component are preferred from the viewpoint of securing high-temperature stability and compatibility between thermoelectric semiconductor fine particles and resin, and from the viewpoint of preventing reduction in the electrical conductivity between thermoelectric semiconductor fine particles. Also preferably, the anion component of the inorganic ionic compound contains a halide anion, more preferably at least one selected from Cl⁻, Br⁻ and I⁻.

Specific examples of the inorganic ionic compound having a potassium cation as the cation component include KBr, KI, KCl, KF, KOH, and K₂CO₃. Among these, KBr and KI are preferred.

Specific examples of the inorganic ionic compound having a sodium cation as the cation component include NaBr, NaI, NaOH, NaF, and Na₂CO₃. Among these, NaBr and NaI are preferred.

Specific examples of the inorganic ionic compound having a lithium cation as the cation component include LiF, LiOH, and LiNO₃. Among these, LiF and LiOH are preferred.

Preferably, the above inorganic ionic compound has an electrical conductivity of 10⁻⁷ S/cm or more, more preferably 10⁻⁶ S/cm or more. When the electrical conductivity falls within the above range, the inorganic ionic compound serving as a conductive assistant can effectively prevent reduction in the electrical conductivity between the thermoelectric semiconductor fine particles.

Also preferably, the decomposition temperature of the inorganic ionic compound is 400° C. or higher. When the decomposition temperature falls within the above range, the inorganic ionic compound can still maintain the effect thereof as a conductive assistant even when the thin film of the thermoelectric semiconductor composition is annealed, as described below.

Preferably, the mass reduction in the inorganic ionic compound at 400° C. in thermogravimetry (TG) is 10% or less, more preferably 5% or less, even more preferably 1% or less. When the mass reduction falls within the above range, the ionic liquid can still maintain the effect thereof as a conductive assistant even when the thin film of the thermoelectric semiconductor composition is annealed, as described below.

The blending amount of the inorganic ionic compound in the thermoelectric semiconductor composition is preferably 0.01 to 50% by mass, more preferably 0.5 to 30% by mass, even more preferably 1.0 to 10% by mass. When the blending amount of the inorganic ionic compound falls within the above range, the electrical conductivity can be effectively prevented from lowering and, as a result, a film having an improved thermoelectric performance can be realized.

In the case where the inorganic ionic compound and the ionic liquid are used together, the total content of the inorganic ionic compound and the ionic liquid in the thermoelectric semiconductor composition is preferably 0.01 to 50% by mass, more preferably 0.5 to 30% by mass, even more preferably 1.0 to 10% by mass.

### (Method for Preparing Thermoelectric Semiconductor Composition)

The method for preparing the thermoelectric semiconductor composition for use in the present invention is not specifically defined. The thermoelectric semiconductor composition may be prepared by mixing and dispersing the above-mentioned thermoelectric semiconductor fine particles, the above-mentioned ionic liquid and the above-mentioned heat-resistant resin, optionally along with any other additives and also with a solvent added thereto, according to a known method using an ultrasonic homogenizer, a spiral mixer, a planetary mixer, a disperser, or a hybrid mixer.

Examples of the solvent include toluene, ethyl acetate, methyl ethyl ketone, alcohols, tetrahydrofuran, methylpyrrolidone, and ethyl cellosolve. One alone or two or more different types of these solvents may be used here either singly or as combined. The solid concentration of the thermoelectric semiconductor composition is not specifically defined so far as the composition may have a viscosity suitable for coating operation.

A thin film of the thermoelectric semiconductor composition may be formed by applying the thermoelectric semiconductor composition onto a substrate and drying it thereon. According to the formation method, a large-area thermoelectric element can be produced in a simplified manner at a low cost.

The thickness of the thin film of the thermoelectric semiconductor composition is not specifically defined, but is, from the viewpoint of the thermoelectric performance and the film strength, preferably 100 nm to 1,000 μm, more preferably 300 nm to 600 μm, even more preferably 5 to 400 μm.

### <Substrate>

As the substrate of the thermoelectric conversion module for use in the present invention, namely, as the first substrate and the second substrate, a plastic film is used not having any influence on reduction in the electrical conductivity of the thermoelectric element layer and on increase in the thermal conductivity thereof. Above all, from the viewpoint that it is excellent in flexibility and that, even when a thin film of a thermoelectric semiconductor composition is annealed, the substrate is not thermally deformed to maintain the performance of the thermoelectric conversion module thereon and therefore has high heat resistance and high dimensional stability, a polyimide film, a polyamide film, a polyether imide film, a polyaramid film or a polyamideimide film is preferred as the plastic film; and from the viewpoint of high versatility thereof, a polyimide film is especially preferred.

The thickness of the plastic film to be used as the substrate is, from the viewpoint of flexibility, heat resistance and dimensional stability, preferably 1 to 1,000 μm, more preferably 10 to 500 μm, and even more preferably 20 to 100 μm.

Also preferably, the 5% weight-loss temperature of the plastic film, as measured in thermogravimetry, is 300° C. or higher, more preferably 400° C. or higher. Also preferably, the rate of dimensional change in heating thereof, as measured at 200° C. according to JIS K7133 (1999), is 0.5% or less, more preferably 0.3% or less. Also preferably, the linear expansion coefficient in the in-plane direction thereof, as measured according to JIS K7197 (2012), is 0.1 ppm·° C.⁻¹ to 50 ppm·° C.⁻¹, more preferably 0.1 ppm·° C.⁻¹ to 30 ppm·° C.⁻¹.

### <Electrode>

The metal material for the electrode on the first and/or second substrates of the thermoelectric conversion module for use in the present invention is gold, nickel, aluminum, rhodium, platinum, chromium, palladium, stainless steel, molybdenum or an alloy containing any of these metals.

The thickness of the electrode layer is preferably 10 nm to 200 μm, more preferably 30 nm to 150 μm, even more preferably 50 nm to 120 μm. When the thickness of the electrode layer falls within the above-mentioned range, the electrical conductivity thereof can be high and the resistance can be low and the electrode layer can have a sufficient strength.

For electrode formation, the above-mentioned metal material for electrodes is used. The method for forming an electrode is the same as the method for forming a solder-receiving layer mentioned above.

The electrode for use in the present invention is required to have high electrical conductivity like the solder-receiving layer, and since an electrode formed according to a plating method or vacuum deposition method can readily realize a high electrical conductivity, a vacuum deposition method such as a vacuum evaporation method, or a sputtering method, as well as an electrolytic plating method or an electroless plating method is preferred. Depending on the dimension of the pattern to be formed and on the dimensional accuracy thereof, a pattern may be formed with ease via a hard mask such as a metal mask. In the case of film formation according to a vacuum deposition method, the substrate to be used may be heated during the process within a range not detracting from the characteristics of the substrate, for the purpose of improving the adhesiveness of the formed film to the substrate used and for the purpose of water removal. In film formation according to a plating method, an electrode layer may be formed according to an electroplating method on the layer previously formed according to an electroless plating method.

In the thermoelectric conversion module of the present invention, a thermoelectric element layer may be used singly, but plural thermoelectric element layers (P-type thermoelectric element layer, N-type thermoelectric element layer) each having a solder-receiving layer that has high solderability may be used by being electrically connected in series to each other via an electrode and in parallel to each other via a thermally insulating flexible sheet, and the thermoelectric conversion module having such a configuration can be used for power generation or for cooling.

### (Method for Producing Thermoelectric Conversion Module)

Production of the thermoelectric conversion module of the present invention includes a step of forming an electrode on the first and second substrates (hereinafter may be referred to as “electrode forming step”), a step of forming a thermoelectric element layer on the electrode on the first substrate (hereinafter may be referred to as “thermoelectric element layer forming step”), a step of annealing the thermoelectric element layer (hereinafter may be referred to as “annealing step”), a step of forming a solder-receiving layer (hereinafter may be referred to as “solder-receiving layer forming step”), and a step of bonding the solder-receiving layer and the electrode on the second substrate via a solder layer (hereinafter may be referred to as “bonding step”).

The steps included in the present invention are described sequentially below.

### (Electrode Forming Step)

The electrode forming step is a step of forming a pattern of the above-mentioned metal material for electrode formation on a first substrate and a second substrate, and the method of forming on a substrate and the patterning method are as described hereinabove.

### (Thermoelectric Element Layer Forming Step)

The thermoelectric element forming step is a step of applying the above-mentioned thermoelectric semiconductor composition to, for example, the first substrate having the first electrode formed as in the above. The method of applying the thermoelectric semiconductor composition to a substrate is not specifically defined, for which employable is any known method of screen printing, flexographic printing, gravure printing, spin coating, dip coating, die coating, spray coating, bar coating, or doctor blade coating. In the case where the coating film is pattern-like formed, preferably employed is screen printing or slot die coating that realizes patterning in a simplified manner using a screen having a desired pattern.

Next, the resultant coating film is dried to give a thin film. As the drying method, employable is any known drying method such as hot air drying, hot roll drying, or IR radiation. The heating temperature is generally from 80 to 150° C., and the heating time is generally from a few seconds to several tens minutes though it varies depending on the heating method.

In the case where a solvent is used in preparing the thermoelectric semiconductor composition, the heating temperature is not specifically defined so far as it falls within a temperature range capable of removing the used solvent through vaporization.

### (Annealing Step)

The annealing step is, for example, a step of annealing the first substrate having the first electrode and the thermoelectric element layer formed thereon as in the above.

The formed thermoelectric element layer is, after thin film formation, preferably further annealed (hereinafter this treatment may be referred to as annealing treatment B). The annealing treatment B stabilizes the thermoelectric performance of the material and promotes the crystal growth of the thermoelectric semiconductor fine particles in the thin film, therefore further enhancing the thermoelectric performance of the material. Not specifically defined, the annealing treatment B is preferably carried out in an inert gas atmosphere such as nitrogen or argon or in a reducing gas atmosphere, in which the gas flow rate is controlled, or in a vacuum condition. Depending on the upper temperature limit of the resin and the ionic compound to be used, the treatment may be carried out at 100 to 500° C. for a few minutes to several tens hours.

### (Solder-Receiving Layer Forming Step)

The solder-receiving layer forming step is a step of laminating a metal material directly on the thermoelectric element layer formed in the above. One layer or two or more layers may be laminated. A composition prepared by putting a metal material in a solvent or a resin may be applied onto the thermoelectric element layer to form the solder-receiving layer. The method for forming on the thermoelectric element layer and the patterning method are as described above.

In the case where a composition prepared by putting a metal material in a solvent or a resin is used for the layer formation, preferably, the resin component including a solvent is removed by firing as the final form of the solder-receiving layer. The firing temperature is not limited so far as it falls within a temperature range capable of maintaining thermoelectric performance.

### (Bonding Step)

The bonding step is, for example, a step of adhering the surface on the solder-receiving layer side of the first substrate, as prepared in the previous solder-receiving layer forming step, and the surface on the second electrode side of the second substrate and bonding them to each other via a solder layer to construct a thermoelectric conversion module.

The solder material to constitute the solder layer for use for the bonding is as described above, and the method of applying the solder material onto the substrate includes known methods of a stencil printing method, a screen printing method and a dispensing method. The heating temperature varies depending on the solder material and the material used for the substrate, but generally heating is carried out at 150 to 280° C. for 3 to 20 minutes.

According to the production method of the present invention, a solder-receiving layer can be formed in a simple method, and with that, the bonding reliability between the thermoelectric element layer containing a resin and a solder layer on the electrode side of the facing substrate can be thereby improved.

### EXAMPLES

Next, the present invention is described in more detail by reference to Examples, but it should be construed that the present invention is not limited to these Examples at all.

The solderability of the test pieces of the thermoelectric conversion modules produced in Examples and Comparative Example was evaluated according to the method mentioned below.

### <Evaluation of Solderability>

### Measurement of Electric Resistance Value

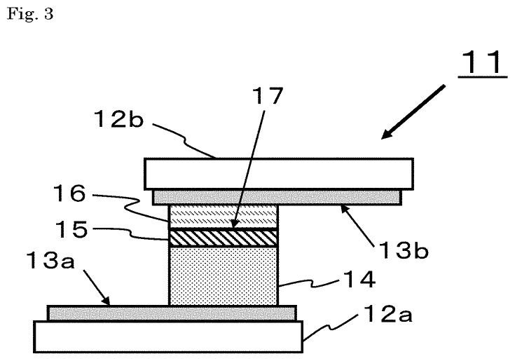

FIG. 3 is a cross-sectional view showing a configuration of a thermoelectric conversion module (test piece) produced in Examples and Comparative Example.

In FIG. 3, the thermoelectric conversion module (test piece) 11 has a first substrate 12a and a second substrate 12b facing each other, and includes a thermoelectric element layer 14, a solder-receiving layer 15 and a solder layer 16 in that order between the electrode 13a formed on the first substrate 12a and the electrode 13b formed on the second substrate 12b, and the solder-receiving layer 15 and the solder layer 16 bond in the bonding part 17 therein.

The electric resistance value between the electrode 13a and the electrode 13b in the test piece of the thermoelectric conversion module produced in Examples and Comparative Example was measured in an environment at 25° C. and 60% RH using a low resistance measuring apparatus (from Hioki E.E. Corporation, Model: RM3545).

### Evaluation of Solderability

Based on the measured electric resistance value, the solderability was evaluated according to the following criteria.
Yes (pass): The electric resistance value is 10⁻²Ω or less (good solderability).
No (fail): The electric resistance value is more than 10⁻²Ω and ∞ (unmeasurable), or bonding failure is confirmed in visual check (no-good solderability).

### Example 1

### <Production of Test Piece of Thermoelectric Conversion Module>

### (1) Production of Thermoelectric Semiconductor Composition

### (Production of Thermoelectric Semiconductor Fine Particles)

Using a planetary ball mill (Premium Line P-7, manufactured by Fritsch Japan Co., Ltd.), a P-type bismuth telluride Bi_{0.4}Te₃Sb_{1.6} (manufactured by Kojundo Chemical Laboratory Co., Ltd., particle size: 180 μm) of a bismuth-tellurium-based thermoelectric semiconductor material was ground in a nitrogen gas atmosphere to give thermoelectric semiconductor fine particles having an average particle size of 2.0 μm. The resultant ground thermoelectric semiconductor fine particles were analyzed for particle size distribution, using a laser diffraction particle size analyzer (from Malvern Corporation, Mastersizer 3000).

### (Preparation of Coating Liquid of Thermoelectric Semiconductor Composition)

92 parts by mass of the P-type bismuth telluride Bi_{0.4}Te_{2.0}Sb_{1.6} fine particles obtained in the above, 3 parts by mass of a polyamic acid being a polyimide precursor as a heat-resistant resin (poly(pyromellitic dianhydride-co-4,4′-oxydianiline)amide acid solution manufactured by Sigma-Aldrich Corporation, solvent: N-methylpyrrolidone, solid concentration: 15% by mass), and 5 parts by mass of an ionic liquid, N-butyl pyridinium were mixed and dispersed to give a coating liquid of a thermoelectric semiconductor composition.

### (2) Formation of Electrode

A copper foil-stuck polyimide film substrate (from Ube Exsymo Co., Ltd., product name: Upicel N, polyimide substrate, thickness: 50 μm, copper foil, thickness: 9 μm) was prepared, and on the copper foil of the polyimide film substrate a nickel layer (thickness: 9 μm) and a gold layer (thickness: 40 nm) were laminated by electroless plating to produce an electrode-having substrate (2 sheets in total).

### (3) Formation of Thermoelectric Element Layer

The coating liquid prepared in the above (1) was applied to the region on the electrode of one substrate (coating area: 0.35 cm×0.35 cm) by screen printing, and then dried at a temperature of 120° C. in an argon atmosphere for 10 minutes to form a thin film having a thickness of 50 μm. Next, the resultant thin film was heated at a heating rate of 5 K/min in an atmosphere of a mixed gas of hydrogen and argon (hydrogen/argon=3 vol %/97 vol %), and kept therein at 325° C. for 1 hour for annealing after thin film formation to attain crystal growth of the fine particles of the thermoelectric semiconductor material to thereby form a thermoelectric element layer.

### (4) Formation of Solder-Receiving Layer

On the thermoelectric element layer formed in (3), a silver paste (from Mitsuboshi Belting Ltd., product name: MDot EC264) as a solder-receiving layer was printed and heated at 120° C. for 10 minutes (thickness: 5.0 μm).

### (5) Formation of Solder Layer and Bonding to Facing Electrode

On the solder-receiving layer formed in (4), a solder paste 42Sn/58Bi alloy (from Tamura Corporation, product name: SAM 10-401-27) was stencil-printed to form a solder layer (thickness before heating: 100 μm), and then the other electrode pattern-having polyimide substrate produced in (2) was laid on it and heated at 180° C. for 5 minutes to thereby bond the solder-receiving layer-having thermoelectric element layer and the facing electrode via the solder layer (thickness after heating and cooling: 50 μm to give a test piece of a thermoelectric conversion module.

The electrical resistance value between the facing electrodes in the resultant thermoelectric conversion module test piece was measured. The result is shown in Table 1.

### Example 2

A test piece of a thermoelectric conversion module was produced in the same manner as in Example 1 except that the thermoelectric semiconductor material was an N-type Bi₂Te₃. The electrical resistance value between the facing electrodes in the resultant thermoelectric conversion module test piece was measured. The result is shown in Table 1.

### Example 3

A test piece of a thermoelectric conversion module was produced in the same manner as in Example 1 except that the solder-receiving layer was a silver layer (thickness: 300 nm) formed according to a vacuum deposition method. The electrical resistance value between the facing electrodes in the resultant thermoelectric conversion module test piece was measured. The result is shown in Table 1.

### Example 4

A test piece of a thermoelectric conversion module was produced in the same manner as in Example 1 except that the solder-receiving layer was an aluminum layer (thickness: 300 nm) formed according to a vacuum deposition method. The electrical resistance value between the facing electrodes in the resultant thermoelectric conversion module test piece was measured. The result is shown in Table 1.

### Example 5

A test piece of a thermoelectric conversion module was produced in the same manner as in Example 1 except that, as the solder-receiving layer, an Sn layer (thickness: 250 nm) and an Au layer (thickness: 50 nm) were formed in that order on the thermoelectric element layer according to a vacuum deposition method. The electrical resistance value between the facing electrodes in the resultant thermoelectric conversion module test piece was measured. The result is shown in Table 1.

### Comparative Example 1

A test piece of a thermoelectric conversion module was produced in the same manner as in Example 1 except that, in Example 1, the solder-receiving layer was not formed. The electrical resistance value between the facing electrodes in the resultant thermoelectric conversion module test piece was measured. The result is shown in Table 1.

TABLE 1

| | | Thermoelectric Element Layer | | | | Electrical | |
|---|---|---|---|---|---|---|---|
| | | | Resin Material | | | Resistance Value | |
| | | Thermoelectric | (blending | | | (Ω) | |
| | | Semiconductor | amount: % by | Solder-Receiving Layer | | [between facing | |
| | Electrode | Material | mass) | Metal Material | Thickness (μm) | electrodes] | Solderability |
| Example 1 | Cu/Ni/Au | P-type Bi_{0.4}Te₃Sb_{1.6} | polyimide (3%) | silver (paste) | 5.0 | 2.0 × 10⁻⁴ | yes |
| Example 2 | Cu/Ni/Au | N-type Bi₂Te₃ | polyimide (3%) | silver (paste) | 5.0 | 1.7 × 10⁻⁴ | yes |
| Example 3 | Cu/Ni/Au | P-type Bi_{0.4}Te₃Sb_{1.6} | polyimide (3%) | silver | 0.30 | 2.9 × 10⁻⁴ | yes |
| Example 4 | Cu/Ni/Au | P-type Bi_{0.4}Te₃Sb_{1.6} | polyimide (3%) | aluminum | 0.30 | 2.2 × 10⁻⁴ | yes |
| Example 5 | Cu/Ni/Au | P-type Bi_{0.4}Te₃Sb_{1.6} | polyimide (3%) | tin/gold | 0.30 | 2.4 × 10⁻⁴ | yes |
| Comparative | Cu/Ni/Au | P-type Bi_{0.4}Te₃Sb_{1.6} | polyimide (3%) | — | — | ∞ (unmeasurable) | no |
| Example 1 | | | | | | | |

It is known that, in Example 1 having a solder-receiving layer, the solderability between the resin-containing thermoelectric element layer and the solder layer on the electrode side of the facing substrate was high, as compared with that in Comparative Example 1 not having a solder-receiving layer (bonding failure was confirmed in visual check). Also it is known that in Examples 2 to 4, the solderability between the resin-containing thermoelectric element layer and the solder layer on the electrode side of the facing substrate was high.

### Industrial Applicability

In the thermoelectric conversion module of the present invention, the solderability between the thermoelectric element layer containing a resin and the solder layer on the facing electrode is stable, and therefore the thermoelectric conversion module of the present invention has high reliability. Simultaneously, the improvement of yield in the production process for the module is expected. Further, the thermoelectric conversion module of the present invention is flexible and has a possibility of thinning the module (with down-sizing and weight reduction).

Specifically, the thermoelectric conversion module of the present invention is considered to be applicable to use for power generation for converting exhaust heat from various combustion furnaces in factories, waste combustion furnaces or cement combustion furnaces, or automobile combustion gas exhaust heat or electronics exhaust heat into electricity. Regarding cooling use, for example, the module can be used for temperature control for various sensors of semiconductor devices, CCD (charge coupled devices), MEMS (micro electro mechanical systems), optical receivers and others, in the field of electronics instruments.

### REFERENCE SIGNS LIST

1A, 1B: Thermoelectric Conversion Module
2a: First Substrate
2b: Second Substrate
3a: First Electrode
3b: Second Electrode
4a: P-type Thermoelectric Element
4b: N-type Thermoelectric Element
5: Solder-Receiving Layer
6: Solder Layer
7: Bonding Part
11: Thermoelectric Conversion Module (test piece)
12a: First Substrate
12b Second Substrate
13a: First Electrode
13b: Second Electrode
14: Thermoelectric Element Layer
15: Solder-Receiving Layer
16: Solder Layer
17: Bonding Part

1. A thermoelectric conversion module comprising a first substrate having a first electrode, a second substrate having a second electrode, a thermoelectric element layer, a solder-receiving layer that directly bonds to the thermoelectric element layer, and a solder layer, wherein the first electrode side of the first substrate and the second electrode side of the second substrate face each other, and wherein the thermoelectric element layer is formed of a thin film of a thermoelectric semiconductor composition containing a resin, and the solder-receiving layer contains a metal material.

2. The thermoelectric conversion module according to claim 1, wherein the metal material is at least one selected from the group consisting of gold, silver, aluminum, rhodium, platinum, chromium, palladium, tin and an alloy that contains a metal material of any of these.

3. The thermoelectric conversion module according to claim 1, wherein the thickness of the solder-receiving layer is 10 nm to 50 μm.

4. The thermoelectric conversion module according to claim 1, wherein the resin is a heat-resistant resin.

5. The thermoelectric conversion module according to claim 4, wherein the heat-resistant resin is a polyimide resin, a polyamide resin, a polyamideimide resin, or an epoxy resin.

6. The thermoelectric conversion module according to claim 1, wherein the thermoelectric semiconductor composition contains a thermoelectric semiconductor material and the thermoelectric semiconductor material is a bismuth-tellurium-based thermoelectric semiconductor material, a telluride-based thermoelectric semiconductor material, an antimony-tellurium-based thermoelectric semiconductor material, or a bismuth-selenide-based thermoelectric semiconductor material.

7. The thermoelectric conversion module according to claim 6, wherein the bismuth-tellurium-based thermoelectric semiconductor material is a P-type bismuth telluride, an N-type bismuth telluride, or Bi₂Te₃.

8. The thermoelectric conversion module according to claim 1, wherein the first substrate and the second substrate each are a polyimide film, a polyamide film, a polyether imide film, a polyaramid film or a polyamideimide film.

9. The thermoelectric conversion module according to claim 1, wherein the thermoelectric element layer is formed of a thin film of a thermoelectric semiconductor composition further containing an ionic liquid.
